(19) United States
(12) Patent Application Publication
(10) Pub. No.: US 2026/0148796 A1
(43) Pub. Date: May 28, 2026

(54) MEMORY DEVICE FOR PERFORMING REPAIR OPERATION BY USING CONVERTED ADDRESS MAPPING, METHOD OF OPERATING THE SAME, AND MEMORY SYSTEM

(71) Applicant: Samsung Electronics Co., Ltd., Suwon-si (KR)

(72) Inventors: Hyungjin Kim, Suwon-si (KR); Hyoukjong Lee, Suwon-si (KR); Jinhun Jang, Suwon-si (KR)

(21) Appl. No.: 19/399,014

(22) Filed: Nov. 24, 2025

(30) Foreign Application Priority Data
Nov. 27, 2024 (KR) 10-2024-0172780
May 14, 2025 (KR) 10-2025-0062818

(51) Int. Cl. G11C 29/00; G06F 7/501

(52) U.S. Cl. CPC G11C 29/76; G06F 7/501; G11C 29/785

(57) ABSTRACT

A memory device for performing a repair operation by using a changed address mapping includes a memory cell array including a plurality of segments, normal ticks, and a spare tick, and a repair circuit configured to generate a first remapping column address constituting a second address mapping different from a first address mapping between a first column address and a first defective column at a first normal tick, and repair multiple first defective columns generated in at least one segment among a plurality of segments.

### CROSS-REFERENCE TO RELATED APPLICATION(S)

This application is based on and claims priority under 35 U.S.C. § 119 to Korean Patent Applications No. 10-2024-0172780, filed on Nov. 27, 2024, and 10-2025-0062818, filed on May 14, 2025, in the Korean Intellectual Property office, the disclosures of which are incorporated by reference herein in their entireties.

### BACKGROUND

Semiconductor chips are manufactured by using a semiconductor manufacturing process, and then are tested by using test equipment in a wafer, die, or package state. Defective portions or defective chips are selected during the test, and when some memory cells are defective, the semiconductor chip is saved by performing a repair thereon. Currently, semiconductor chips such as dynamic random access memories (DRAMs) are increasingly likely to suffer errors in the manufacturing process as fine processes increase. In addition, even when errors have not been detected during the initial test operation, an error may occur during the chip operation.

### SUMMARY

The present disclosure relates to an electronic device, and more particularly, to a memory device which performs a column repair operation by changing a column address mapping based on a mathematical operation bit table, a method of operating the memory device, and a memory system.

The disclosure provides a memory device for performing a repair operation without storing an address of a defective column in a fuse array, a method of operating the memory device, and a memory system.

A source-destination repair operation may, as a method of repairing the defective column detected during the test, store the addresses of the defective columns detected during the test and the addresses of normal columns to replace the defective columns in a fuse array in the DRAM, replace the defective columns with the normal columns, and replace the normal columns with redundancy columns.

When a plurality of fuses are used to store addresses of defective columns in the source-destination repair operation, a large number of fuses are required according to the number of addresses of the defective columns. An issue of the size increase of DRAM, an issue of the lack of a fuse array space for storing defective column addresses, and an issue of reduction in the performance of DRAM due to the occurrence of time for identifying the addresses of the defective columns, may occur. In addition, it may be necessary to store in the fuse array the addresses of multi-defective columns where columns at the same locations are detected as defective. In general, multi-defective columns have a lower probability of occurrence than single-defect columns, but there is an issue that fuses are excessively used to prepare for multi-defective columns and thus, resources are unnecessarily consumed.

Accordingly, when the repair operation may be performed without storing the addresses of the defective columns in the fuse array, it may be possible to satisfy reliability availability serviceability (RAS) expectation by using limited repair resources (for example, the fuse array), reduce the size of DRAM, and improve DRAM performance.

According to an aspect of the disclosure, there is provided a memory device including a memory cell array including a plurality of rows divided into a plurality of segments, a plurality of columns divided into a plurality of normal ticks corresponding to a burst data set corresponding to a burst length, and a plurality of redundancy columns of a spare tick, and a repair circuit, configured to, based on a first column address and at least one piece of operation data that is pre-stored, generate a first remapping column address constituting a second address mapping that is different from a first address mapping that maps between the first column address and a first defective column at a first normal tick, and based on the first remapping column address, repair multiple first defective columns in at least one segment among the plurality of segments using at least one redundancy column of the plurality of redundancy columns of the spare tick.

In addition, according to another aspect of the disclosure, there is provided a method of operating a memory device, the method including, based on a first column address input to the memory device and at least one piece of operation date, generating a first remapping column address constituting a second address mapping that is different from a first address mapping that maps between a first column address and a first defective column at a first normal tick of the memory device, and repairing multiple first defective columns in at least one segment among a plurality of segments of the memory device with at least one redundancy column of a spare tick.

In addition, according to another aspect of the disclosure, there is provided a memory system including a host configured to generate a command and an address, and a memory device configured to access a burst data set corresponding to a burst length, based on the command and the address. The memory device includes a memory cell array including a plurality of rows divided into a plurality of segments, a plurality of columns divided into a plurality of normal ticks corresponding to a burst data set corresponding to a burst length, and a plurality of redundancy columns of a spare tick, and a repair circuit configured to, based on a first column address and at least one piece of operation data that is pre-stored, generate a first remapping column address constituting a second address mapping that is different from a first address mapping that maps between the first column address and a first defective column, and based on the first remapping column address, repair multiple first defective columns in at least one segment among the plurality of segments using at least one redundancy column of the plurality of redundancy columns of the spare tick.

### BRIEF DESCRIPTION OF THE DRAWINGS

Implementations of the disclosure will be more clearly understood from the following detailed description taken in conjunction with the accompanying drawings in which:

FIG. 1 is a block diagram of a memory system according to some implementations;

FIG. 2 is a diagram of a structure according to a row direction and a column direction of a memory cell array, according to some implementations;

FIGS. 3A and 3B are example diagrams of defective columns and repair columns generated in particular segments, according to implementations;

FIG. 4 is a diagram for describing repair operations of a memory device illustrated in FIG. 1;

FIG. 5 is a block diagram of a repair address storage circuit according to some implementations;

FIG. 6 is an example circuit diagram of a fuse box included in the repair address storage circuit of FIG. 5;

FIG. 7 is a diagram for describing operations of each of a repair address storage circuit, a column repair circuit, and a column decoder, according to some implementations;

FIGS. 8A, 8B, 8C, and 8D are block diagrams of column address conversion circuits according to implementations, respectively;

FIG. 9 is a diagram of a fuse box storing shared operation data according to some implementations;

FIG. 10 is a circuit diagram of a repair address storage circuit including the fuse box of FIG. 9;

FIG. 11 is an example diagram of the fuse box included in the repair address storage circuit of FIG. 10;

FIG. 12 is a diagram of fuse boxes storing shared operation data according some implementations;

FIG. 13 is a circuit diagram of a column decoding and column selection line driver according to some implementations;

FIGS. 14 and 15 are example diagrams of semiconductor packages including repair circuits of the disclosure;

FIG. 16 is a block diagram of a system including a repair circuit of the disclosure; and

FIG. 17 is a flowchart of a method of operating a memory device, according to some implementations.

### DETAILED DESCRIPTION OF THE EMBODIMENTS

Hereinafter, embodiments of the disclosure will be described in detail with reference to the accompanying drawings.

Ordinal expressions, such as ‘first’, ‘second’, ‘third’, and ‘fourth’, used in the disclosure may modify various components regardless of the order and/or importance, and may be used to distinguish one component from another component, but are not limited to the corresponding components. For example, a first user device and a second user device may refer to different user devices, regardless of the order or importance. For example, without departing from the scope of the disclosure, the first component may be referred to as the second component, and similarly, the second component may also be referred to as the first component. In the disclosure, the first components may be referred to as the first component, the second component, a third component, a fourth component, a fifth component, a sixth component, or the like, in the claims, and the second components in the disclosure may be referred to as the first component, the second component, the third component, or the like, in the claims.

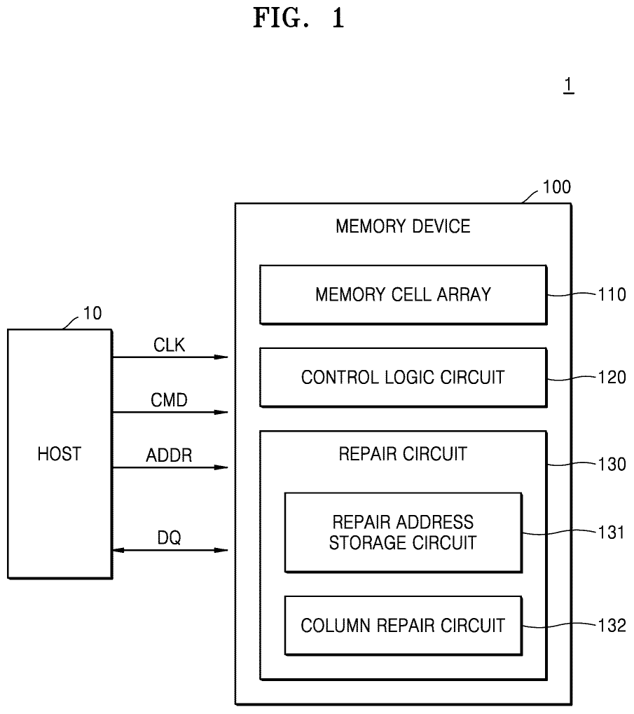

FIG. 1 is a block diagram of a memory system 1 according to some implementations.

Referring to FIG. 1, the memory system 1 may include a host 10 and a memory device 100.

The host 10 may communicate with the memory device 100 via an interface. To this end, a channel including a bus physically or electrically connecting the host 10 to the memory device 100 may be provided. For example, the host 10 may provide a clock signal CLK to the memory device 100 via a clock bus, a command CMD to the memory device 100 via a command bus, and an address ADDR to the memory device 100 via an address bus. For example, the host 10 may provide data DQ to the memory device 100 or receive the data DQ from the memory device 100 via the data bus. In FIG. 1, each bus may include one or more signal lines through which signals are provided.

In some implementations, the host 10 may be included in test equipment for testing the memory device 100. The host 10 may include a processor, such as a central processing unit (CPU) or an application processor (AP), which controls hardware, software, and firmware to perform a test operation on the memory device 100. The host 10 may transmit a test signal to the memory device 100, or receive a test result value for the test signal of the memory device 100. The host 10 may be implemented as a test program including a test algorithm or a pattern for performing the test operation. For example, after a particular piece of data is stored in a memory cell array 110 of the memory device 100, the host 10 may determine a pass or fail of the test operation according to whether the read data is the same as the particular piece of data. The host 10 may test the memory device 100 to determine whether the range of change is in an allowable range, by measuring changes in voltage, current, and/or frequency under various driving conditions.

During the test, the host 10 may provide a write command and a related address to the memory device 100, and the memory device 100 may perform a write operation to write data to a memory location corresponding to the related address. During the test, the host 10 may provide a read command and a related address to the memory device 100, and the memory device 100 may perform a read operation to read data from a memory location corresponding to the related address, and output the read data. During the test, the host 10 may detect the defect address, and provide the detected defect address to the memory device 100. The host 10 may store the defect address in a non-volatile memory (for example, a fuse box) in the memory device 100, and instruct the memory device 100 to perform the repair operation on the defect address.

The memory device 100 may replace a defective word line selected by the defect address with a redundancy word line, or may perform the repair operation of replacing a defective bit line selected by the defect address with a redundancy bit line. The memory device 100 may be implemented as dynamic random access memory (DRAM), but is not limited thereto. For example, the memory device 100 may be implemented as double data rate (DDR) synchronous DRAM (SDRAM) (DDR SDRAM), low power DDR (LPDDR) SDRAM (LPDDR SDRAM), graphics DDR (GDDR) SDRAM (GDDR SDRAM), etc. Alternatively, the memory device 100 may be implemented as static RAM (SRAM), a high bandwidth memory (HBM), or a processor-in-memory (PIM).

The memory device 100 may include a memory cell array 110, a control logic circuit 120, and a repair circuit 130.

The memory cell array 110 may include a plurality of rows (or a plurality of word lines), a plurality of columns (or a plurality of bit lines), and a plurality of memory cells. The plurality of memory cells may be formed at points at which the plurality of rows intersect the plurality of columns intersect, respectively. In addition, when a defect or flaw occurs in a memory cell, the memory cell array 110 may include redundancy rows (or a plurality of redundancy word lines) and/or redundancy columns (or a plurality of redundancy bit lines), to which redundancy memory cells are connected for repairing defective memory cells. In some implementations, in the memory cell array 110, the plurality of rows may be respectively divided into a plurality of segments, and the plurality of columns may be respectively divided into a plurality of ticks. The plurality of ticks may include a plurality of normal ticks corresponding to burst data of the burst length in each of the segments, and a spare tick that repairs a defective column of the normal ticks with a redundancy column. The defective column may include a column including at least one fail cell from at least one bit line included in the corresponding column.

The control logic circuit 120 may control access to the memory cell array 110 based on the command CMD and the address ADDR.

The repair circuit 130 may be configured to repair defective memory cells detected in the memory cell array 110 with redundancy memory cells. The repair circuit 130 may repair defective cells detected by using an electrical die sorting (EDS) test after a semiconductor manufacturing process of the memory device 100. In addition, the repair circuit 130 may perform a post package repair operation to repair the defective memory cells that occur during a package test, a module test, and/or a mounting test of the memory device 100 with the redundancy memory cells.

The repair circuit 130 may be configured to generate a first remapping column address constituting a second address mapping different from the first address mapping between a first column address and a first defective column in a first normal tick, based on the first column address and at least one pre-stored piece of operation data. In addition, the repair circuit 130 may be configured to repair multiple first defective columns generated from at least one segment among a plurality of segments with the redundancy columns of the spare tick.

The repair circuit 130 may be configured to generate a remapping column address constituting a one-to-one basis address mapping different from the first address mapping between the first column address and the defective column in each normal tick, based on the first column address and the at least one pre-stored piece of operation data. In addition, the repair circuit 130 may be configured to repair the multiple defective columns generated from at least one segment with the redundancy columns of the spare tick.

The repair circuit 130 may configure a second remapping column address constituting a third address mapping different from the second address mapping in a second normal tick based on the first column address and at least one piece of operation data.

The repair circuit 130 may be configured to generate some bits of the remapping column address, by performing a mathematical operation on an upper bit corresponding to a bit number of the at least one piece of operation data among the plurality of bits of the first column address and on the plurality of bits of the at least one piece of operation data. In addition, the repair circuit 130 may be configured to generate the remaining bits of the remapping column address, by bypassing the remaining bits except for the upper bits among the plurality of bits of the first column address.

The repair circuit 130 may include a repair address storage circuit 131 and a column repair circuit 132, to repair the defective columns detected in the memory cell array 110 with the redundancy columns during the test.

The repair address storage circuit 131 may store at least one piece of operation data. In some implementations, the repair address storage circuit 131 may store operation data individually stored for each normal tick and segment. In some implementations, the repair address storage circuit 131 may store the shared operation data stored individually for each normal tick, and segment master data indicating whether to apply the shared operation data for each segment in one normal tick. In some implementations, the repair address storage circuit 131 may store the shared operation data, and tick master data indicating whether to apply the shared operation data for each normal tick.

The column repair circuit 132 may be configured to perform a mathematical operation on a column address and at least one piece of operation data. In addition, the column repair circuit 132 may generate the remapping column address as a result of the mathematical operation.

Although not illustrated in FIG. 1, the memory device 100 may further include an address buffer (or address register), a row decoder, a column decoder, an input/output (I/O) gating circuit, a data I/O buffer, a refresh control circuit, an error correction code (ECC) engine, etc.

As described above, by reducing the size of the fuse box including the fuse array, the size of the memory device 100 may be reduced.

In addition, as described above, by performing a repair operation without storing the address of the defective column in the fuse array, the performance of the memory device 100 may be improved.

In addition, as described above, by efficiently managing repair resources, the yield of the device may be improved and the reliability availability serviceability (RAS) expectation of the device may be satisfied.

DRAM soft error rate (SER) (DRAM SER) may represent the possibility that an error in a memory cell in DRAM may occur due to natural radiation or other external factors, and as a result, damage to data may occur. An SER defect may be known as a soft error, and may generally occur in the form of a data bit being switched on or off without any damage to hardware.

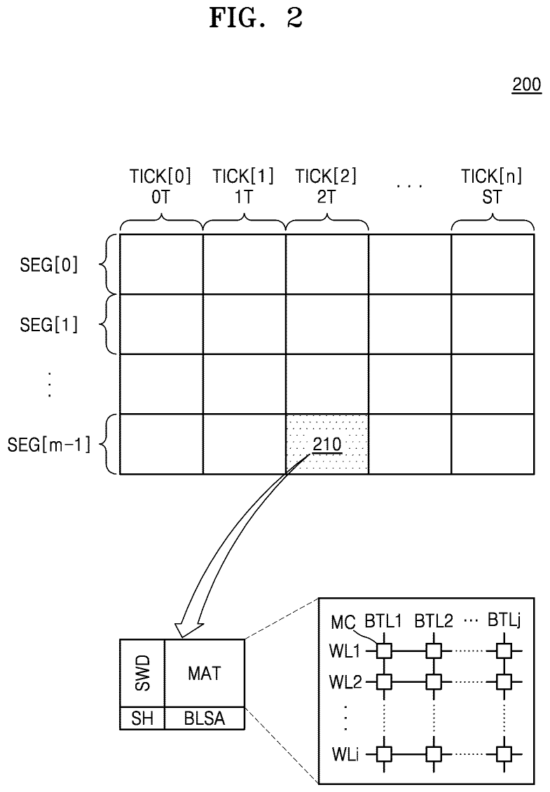

FIG. 2 is a diagram of a structure according to a row direction and a column direction of a memory cell array 200, according to some implementations. The memory cell array 200 of FIG. 2 may correspond to the memory cell array 110 in FIG. 1.

Referring to FIG. 2, the memory cell array 200 may be divided into m (where m is a natural number) segments (SEG[0] through SEG[m-1]) divided in the row direction and n+1 (where n is a natural number) ticks (TICK[0] through TICK[n]) divided in the column direction. The memory cell array 200 may include a plurality of core units 210 divided into segments and ticks. The core unit 210 may include a sub-word line driver SWD driving a word line, a bit line sense amplifier BLSA detecting a voltage of a bit line, a sub-hole SH controlling the bit line sense amplifier BLSA, and a memory array tile MAT. The memory array tile MAT may include i (i is a natural number) word lines (WL1 through WLi), j (j is a natural number) bit lines (BTL1 through BTLj), and a plurality of memory cells MC. Each memory cell MC may be arranged at a point where the word line intersects the bit line.

In each of the m segments (SEG[0] through SEG[m-1]), the n ticks (TICK[0] through TICK[n-1]) may be configured to store burst data corresponding to a burst length BL set in the memory device 100. The ticks that store burst data corresponding to the burst length BL, for example, 0T tick TICK[0], 1T tick TICK[1], and 2T tick TICK[2] through n-1T tick TICK[n-1]), may be referred to as normal ticks. The tick TICK[n] may be configured to be used as a spare tick or redundancy tick to repair the defective column occurring in the n ticks (TICK[0] through TICK[n-1]) with the redundancy column. The tick TICK[n] may be used as a spare tick having a concept contrasting to the normal tick, and may be referred to as an ST (Spare Tick) tick.

In some implementations, the memory cell array 200 may be divided into various numbers of ticks according to the burst length BL set in the memory device 100. A defective column included in ticks storing data corresponding to a burst length may be repair with a redundancy column of the ST tick. To perform the column repair operation efficiently, the memory cell array 200 may include various numbers of segments. In some implementations, when the burst length BL is set to 16, m segments (SEG[0] through SEG[m-1]) may include 17 ticks (TICK[0] through TICK[16]). The 0T tick TICK[0] may be configured to store first burst data (for example, BL0). The 1T tick TICK[1] may be configured to store second burst data (for example, BL1). The 15T tick TICK[15] may be configured to store the last (or a sixteenth) burst data (for example, BL15). The 16T tick TICK[16] may be configured to be used as ST tick to repair the defective bit line generated in the 16 ticks (TICK[0] through TICK[15]).

In some implementations, the memory cell array 200 may further include an ECC tick that stores the ECC generated based on a data set when the burst length BL is 16. The ECC tick may be referred to as the normal tick. In this case, each of the m segments (SEG[0] through SEG[m-1]) may include 18 ticks (TICK[0] through TICK[17]). Among the 18 ticks (TICK[0] through TICK[17]), the 16 ticks (TICK[0] through TICK[15]) may store a data set when the burst length BL is 16, 16T tick TICK[16] may store ECC data, and 17T tick TICK[17] may be used as the ST stick.

In some implementations, when the burst length BL is set to 32, the memory cell array 200 may include 16 ticks (TICK[0] through TICK[15]) that store a first burst data set for the case when the burst length BL is 16, 16T tick TICK[16] that stores the ECC data for the first burst data set, 16 ticks (TICK[17] through TICK[32]) that store a second burst data set for the case when the burst length BL is 16, 33T tick TICK[33] that stores the ECC data for the second burst data set, and 34T tick TICK[34] that is used as the ST tick.

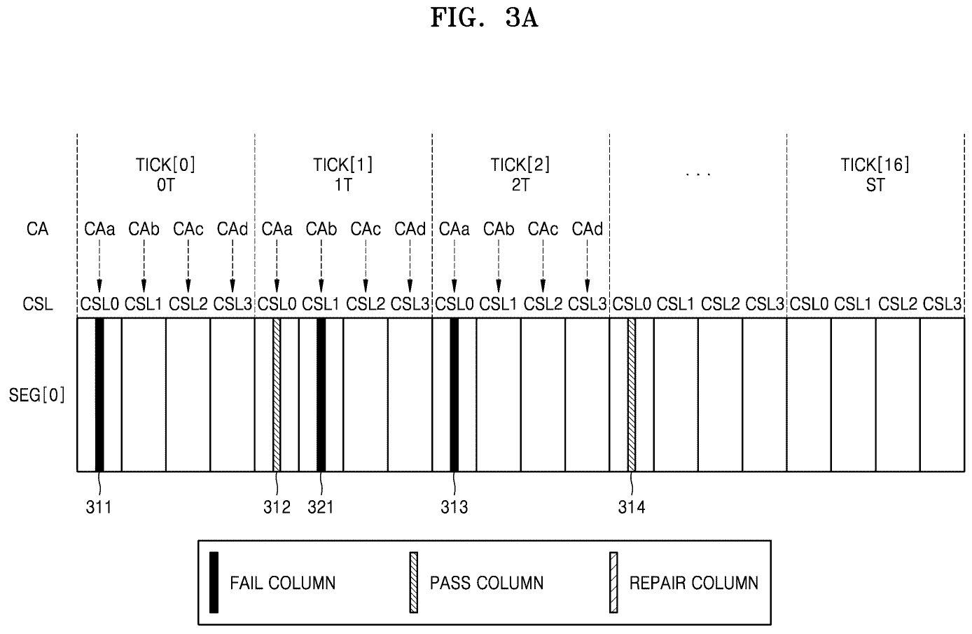

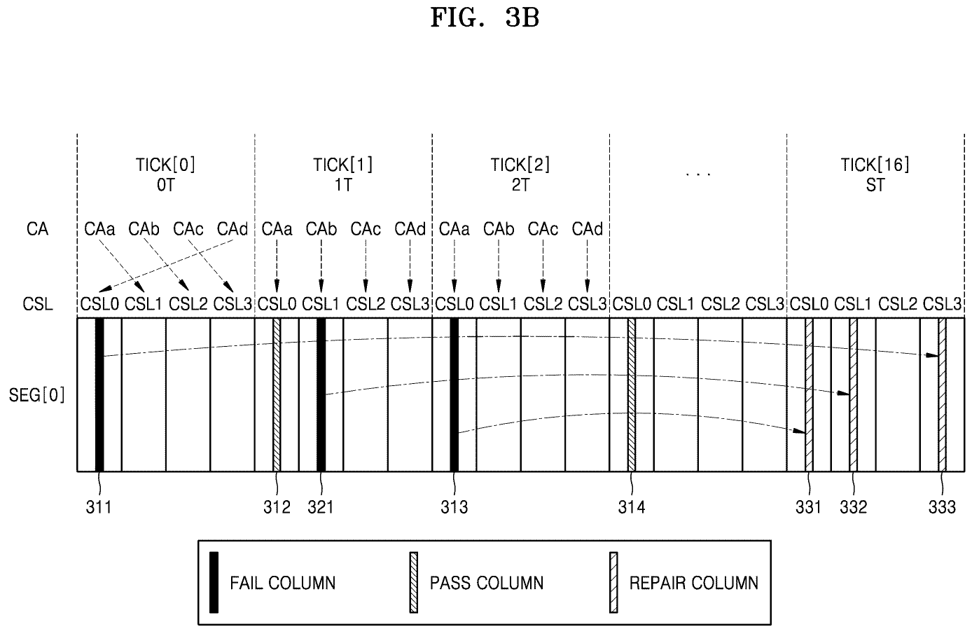

FIGS. 3A and 3B are example diagrams of the defective columns and the repair columns generated in particular segments, according to implementations. Specifically, FIG. 3A is a diagram of the defective columns, and FIG. 3B is an example diagram of the repair columns for the defective columns in FIG. 3A. In FIGS. 3A and 3B, the defective columns generated in a particular segment among the m segments (SEG[0] through SEG[m-1]) in FIG. 2, for example, in the segment SEG[0] (or referred to as a first segment), are described as examples. However, the disclosure is not limited to the segment SEG[0] of FIGS. 3A and 3B, and descriptions to be given with reference to FIGS. 3A and 3B may also be applied to m-1 segments (SEG[1] through SEG[m-1]). On the other hand, for convenience of description, the burst length BL is assumed as 16.

Referring to FIG. 3A, each of the 17 ticks (TICK[0] through TICK[16]) corresponding to the segment SEG[0] may store data corresponding to the burst length BL (for example, burst data), and the data corresponding to the burst length BL may be accessed via a bit line selected by a column selection line signal CSL. The column selection line signal CSL may be generated by decoding the column address. For example, each of the 17 ticks (TICK[0] through TICK[16]) corresponding to the segment SEG[0] may include four columns, and the four columns may be designed to be selected by four column selection line signals (CSL0, CSL1, CSL2, and CSL3). Referring to FIG. 3A, for example, when a column address CAa is input to the memory device 100, the column selection line signal CSL0 (or, referred to as a first column selection line signal) may be generated, and a column having a column selection line address corresponding to the column selection line signal CSL0 among the four columns may be accessed. When a column address CAb is input to the memory device 100, a column selection line signal CSL1 (or, referred to as a second column selection line signal) may be generated, and a column having a column selection line address corresponding to the column selection line signal CSL1 among the four columns may be accessed. When a column address CAc is input to the memory device 100, a column selection line signal CSL2 (or, referred to as a third column selection line signal) may be generated, and a column having a column selection line address corresponding to the column selection line signal CSL2 among the four columns may be accessed. When a column address CAd is input to the memory device 100, a column selection line signal CSL3 (or, referred to as a fourth column selection line signal) may be generated, and a column having a column selection line address corresponding to the column selection line signal CSL3 among the four columns may be accessed. In other words, during the test, the column address CAa may be mapped to the first column selection line signal CSL0, the column address CAb may be mapped to the second column selection line signal CSL1, the column address CAc may be mapped to the third column selection line signal CSL2, and the column address CAd may be mapped to the fourth column selection line signal CSL3. A column address CA and the column selection line signal CSL may be mapped on a one-to-one basis. According to some implementations, the 17 ticks (TICK[0] through TICK[16]) may include various numbers of columns, and each of the columns may be accessed by a corresponding column selection line signal.

For example, a burst data set output by the first column selection line signal CSL0 may include BL0 burst data, BL1 burst data, BL2 burst data, . . . , BL15 burst data, which are output from columns 311, 312, 313, 314, . . . ,) corresponding to the first column selection line signal CSL0 in each of the 16 ticks (TICK[0] through TICK[15]). On the other hand, a burst data set output by the second column selection line signal CSL1 may include BL0 through BL15 burst data output from columns corresponding to the second column selection line signal CSL1 in each of the 16 ticks (TICK[0] through TICK[15]). Similarly, the burst data set output by the third column selection line signal CSL2 or the fourth column selection line signal CSL3 may include the burst data set BL0 through BL15 from columns corresponding to the fourth column selection line signal CSL3 or the fourth column selection line signal CSL3 in each of the 16 ticks (TICK[0] through TICK[15]).

On the other hand, the defective column may be detected by the host 10 included in the test equipment, in the segment SEG[0] during the test. Referring to FIG. 3A, for example, in the segment SEG[0], the column 311 of the 0T tick TICK[0] and the column 313 of the 2T tick TICK[2] may be detected as defective columns, and the column 312 of the 1T tick TICK[1] and the columns of the remaining ticks (TICK[3] through TICK[15]) may be detected as good columns. The columns 311 and 313 detected as defective columns in the segment SEG[0] may be arranged at physical positions corresponding to the first column selection line signal CSL0, and in this manner, two or more defective columns selected by the same column selection line signal may be referred to as multi-defective columns or multi-CSL fail columns. Referring to FIG. 3A, for example, in the segment SEG[0], the column 321 of the 1T tick TICK[1] may be the defective column. The column 321 of the 1T tick TICK[1] may be referred to as a single defective column or a single CSL fail column.

Referring to FIG. 3B, when a multi-defective column is detected during a test, address mapping in at least one tick, in which a multi-defective column is detected, may be changed. The address mapping may include mapping between a column address and a column selection line signal. Information for changing the address mapping may be stored in the repair address storage circuit 131 of the repair circuit 130 in the form of the fuse box. Referring to FIG. 3B, for example, when the columns 311 and 313 are detected as multi-defective columns, address mapping at the 0T tick TICK[0] including the column 311 may be changed differently from that illustrated in FIG. 3A. Even when the address mapping is changed, the column address CA and the column selection line address corresponding to the column selection line signal CSL may be mapped on a one-to-one basis. On the other hand, as another example, the address mapping in the 2T tick TICK[2] including the column 313 may also be randomly changed on a one-to-one basis. When the address mapping is randomly mapped on a one-to-one basis, the defective column in the segment SEG[0] may be changed to a single defective column, on the basis of the column address CA of the host 10.

The columns 311, 313, and 321 detected as defective columns may be repaired with the redundancy columns 331, 332, and 333 of the ST sticks. In this case, a repair condition may be determined so that resources of the ST ticks (for example, 16T tick TICK[16]) including the redundancy columns do not overlap each other, and a burst operation of the memory device 100 may be supported. Referring to FIG. 3B, for example, the column 311 of the 0T tick TICK[0] may be repaired with the redundancy column 333 of the ST tick (for example, the 16T tick TICK[16]). The column 321 of the 1T tick TICK[1] may be repaired with the redundancy column 332 of the ST tick (for example, 16T tick TICK[16]). The column 313 of the 2T tick TICK[2] may be repaired with the redundancy column 331 of the ST tick (for example, 16T tick TICK[16]).

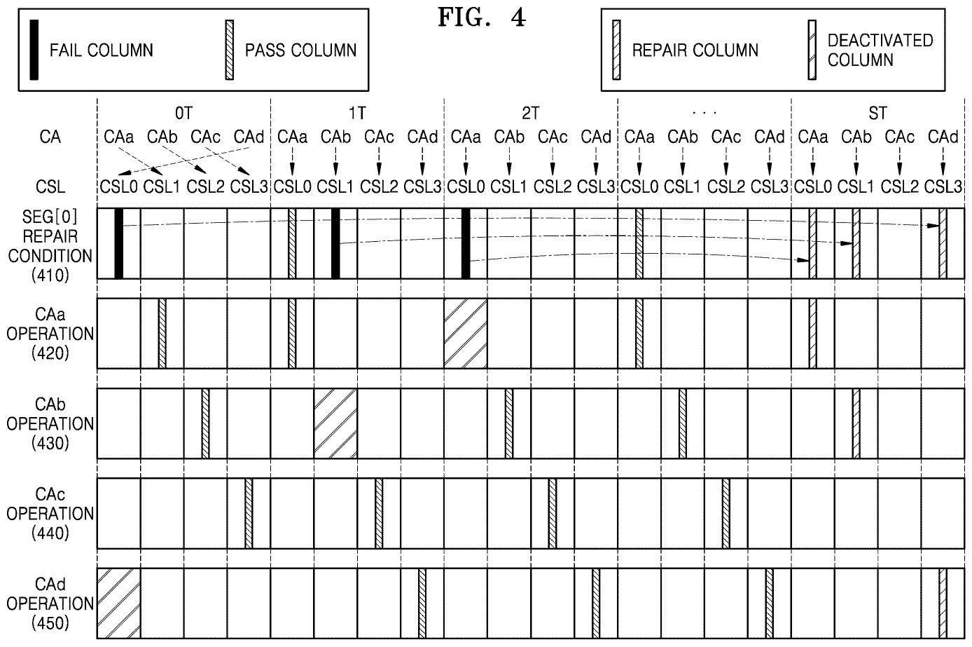

FIG. 4 is a diagram for describing repair operations of the memory device 100 illustrated in FIG. 1. In FIG. 4, the repair operation is described based on the segment SEG[0] in which the burst length BL is 16. However, the disclosure is not limited thereto. It is assumed that repair condition 410 in FIG. 4 is as that illustrated in FIG. 3B.

Referring to FIG. 4, in the case of operation 420 for the accessed column address CAa, a column corresponding to the second column selection line signal CSL1 may be selected at 0T tick TICK[0], a column corresponding to the first column selection line signal CSL0 may be selected at the 1T tick TICK[1], and a column corresponding to the first column selection line signal CSL0 on the 2T tick TICK[2]. In the case of operation 430 for the accessed column address CAb, a column corresponding to the third column selection line signal CSL2 may be selected at the 0T tick TICK[0], a column corresponding to the second column selection line signal CSL1 of the ST tick may be selected at the 1T tick TICK[1], and a column corresponding to the second column selection line signal CSL1 may be selected at the 2T tick TICK[2]. In the case of operation 440 for the accessed column address CAc, a column corresponding to the fourth column selection line signal CSL3 may be selected at the 0T tick TICK[0], and a column corresponding to the third column selection line signal CSL2 may be selected at each of the 1T tick TICK[1] and the 2T tick TICK[2]. In the case of operation 450 for the accessed column address CAd, a column corresponding to the fourth column selection line signal CSL3 of the ST tick may be selected at the 0T tick TICK[0], and a column corresponding to the fourth column selection line signal CSL3 may be selected at each of the 1T tick TICK[1] and the 2T tick TICK[2].

In some implementations, columns detected as defective columns may be deactivated in a corresponding operation, as illustrated in FIG. 4. However, the disclosure is not limited to the implementations described above. According to some implementations, all columns detected as defective columns in operations 420, 430, 440 and 450 for the accessed column addresses CAa, Cab, CAc, and Cad may be deactivated.

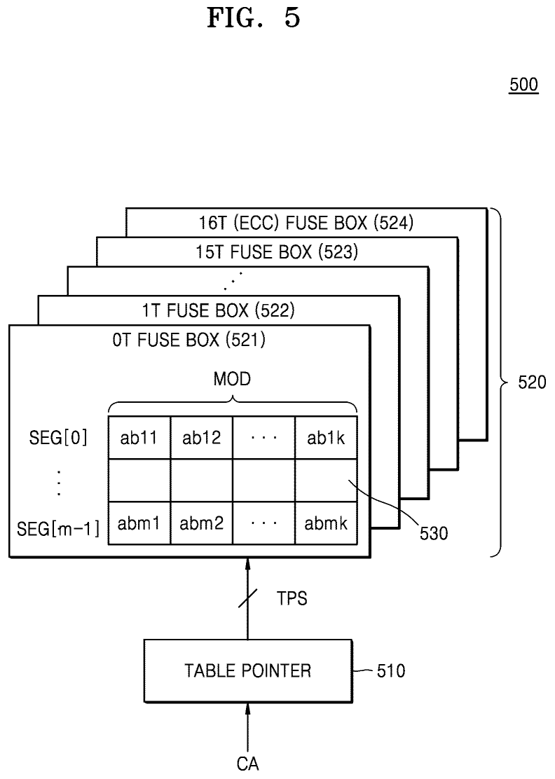

FIG. 5 is a block diagram of a repair address storage circuit 500 according to some implementations.

Referring to FIG. 5, the repair address storage circuit 500 may correspond to the repair address storage circuit 131 in FIG. 1. In some implementations, the repair address storage circuit 500 may be configured to store operation data MOD set for each of the normal ticks (for example, the 0T tick TICK[0] through 16T tick TICK[15]) and the plurality of segments (for example, m segments (SEG[0] through SEG[m-1])).

The repair address storage circuit 500 may include a table pointer 510 and a plurality of fuse boxes 520.

The table pointer 510 may generate a table pointing signal TPS based on the column address CA. The table pointing signal TPS may include a signal that provides position information about the plurality of fuse boxes 520.

Each of the plurality of fuse boxes 520 may store the plurality of pieces of operation data MOD for each of the m segments (SEG[0] through SEG[m-1]). In some implementations, when the burst length BL is set to 16, the plurality of fuse boxes 520 may include 17 fuse boxes. For example, 16 fuse boxes may store segment-specific operation data MOD for 16 ticks configured to store the burst data set, and one fuse box may store segment-specific operation data MOD for one tick configured to store the ECC data. For example, a 0T fuse box 521 may store the operation data MOD for changing the address mapping of the columns included in the 0T tick TICK[0] (for example, referred to as the first normal tick) for each of the segments (SEG[0] through SEG[m- 1]). A 1T fuse box 522, a 15T fuse box 523, and a 16T fuse box 524 may store the operation data MOD for changing the address mapping of the columns included in each of the segments (SEG[0] through SEG[m-1]).

The operation data MOD may include data for changing the addressing of the columns included in a particular tick. The segment-specific operation data MOD may be stored in the form of a table in a fuse box. Because mathematical operations include logical operations, arithmetic operations, or the like, the operation data MOD may include at least one bit for a logical operation and/or an arithmetic operation. For example, in the case of the 0T fuse box 521, the operation data MOD corresponding to the segment SEG[0] may include k (k is a natural number) bits (ab11, ab12, . . . , ab1k). The operation data MOD corresponding to the segment SEG[m-1] may include k bits (abm1, abm2, . . . , abmk). However, the disclosure is not limited to the implementations described above.

In some implementations, in a tick in which the defective column is not detected, k bits (ab11, ab12, . . . , ab1 k) of the operation data MOD may be 0. In this case, the address mapping may be the same before and after the test.

In some implementations, the number of fuses included in the plurality of fuse boxes 520 may be based on the number of segments, the number of bits of one piece of operation data, and the number of normal ticks. For example, when the operation data MOD includes three bits, and the memory cell array 200 is divided into four segments (SEG[0] through SEG[3]), each of the plurality of fuse boxes 520 may include 3*4=12 fuses 530. Accordingly, the repair address storage circuit 500 may include 12*17=204 fuses 530 for 17 ticks. According to the disclosure, the repair operation, by using fewer fuses than the number of fuses required for the source-destination repair operation, the memory device 100 of the disclosure may be designed to have a smaller size than a memory device performing the source-destination repair operation. A source-destination repair operation may include a repair operation using a source address representing a defective column address and a destination address representing a repair column, and a repair operation using a source address representing an address and the destination address representing the repair column, and a fuse box of a memory device performing the source-destination repair operation may include a plurality of fuses for storing a plurality of bits representing each of the source address and the destination address.

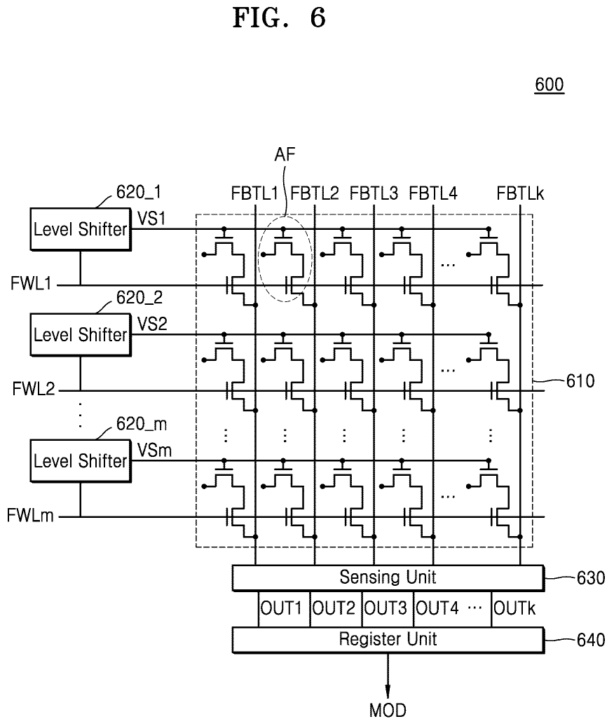

FIG. 6 is an example circuit diagram of a fuse box 600.

Referring to FIG. 6, the fuse box 600 may represent any one of the plurality of fuse boxes 520 in FIG. 5. For example, the fuse box 600 may correspond to the 0T fuse box 521 in FIG. 5. The fuse box 600 may include a fuse array 610, m level shifters (620_1 through 620_ m), a sensing unit 630, and a register unit 640.

The fuse array 610 may include m word lines (FWL1, FWL2, . . . , FWLm), k bit lines (FBTL1, FBTL2, FBTL3, FBTL4, . . . , FBTLk), and a plurality of fuses AF. The plurality of fuses AF may be arranged at points where m word lines (FWL1, FWL2, . . . , FWLm) and k bit lines (FBTL1, FBTL2, FBTL3, FBTL4, . . . , FBTLk) intersect with each other. Data may be stored in each of the plurality of fuses AF. The plurality of fuses AF may include laser fuses, electrical fuses, or anti-fuses. The anti-fuse may have a characteristic that its state is converted from a high resistance state to a low resistance state by an electrical signal (for example, a high voltage signal). In some implementations, it is assumed that the plurality of fuses AF are implemented as anti-fuses. The number of fuses AF may be m*k. The m word lines (FWL1, FWL2, . . . , FWLm) may be provided in the fuse array 610 to access the fuses AF arranged in m rows, and the k bit lines (FBTL1, FBTL2, FBTL3, FBTL4, . . . , FBTLk) may be provided in the fuse array 610 to transmit data read from the fuses AF arranged in one row. In the fuses AF corresponding to one row, k bits representing the operation data MOD for one segment may be stored, and in one fuse AF, one bit may be stored. Referring to FIGS. 5 and 6, for example, in the fuses AF connected to the word line FWL1, k bits (ab11, ab12, . . . , ab1k) for the segment SEG[0] may be stored.

The m level shifters (620_1 through 620_m) may respectively generate m voltage signals (VS1 through VSm) having high voltages for changing the resistance state of the fuse AF. By applying the m voltage signals (VS1 through VSm) to the fuse array 610, the m level shifters (620_1 through 620_m) may change the state of the fuse AF of the fuse array 610, and the fuse AF selected from the fuse array 610 may be programmed by using the breakdown of a dielectric layer.

After the fuse array 610 is programmed, a read operation on the fuse array 610 may be performed together with a driving start of the memory device 100. The read operation on the fuse array 610 may be performed simultaneously with the driving of the memory device 100, or may also be performed after a certain set time from the driving time point of the memory device 100. Word line selection signals may be provided via the m word lines (FWL1, FWL2, . . . , FWLm), and data stored in the selected fuses may be provided to the sensing unit 630 via the k bit lines (FBTL1, FBTL2, FBTL3, FBTL4, . . . , FBTLk). Due to characteristics of an array structure, data in the fuse array 610 may be accessed randomly.

The sensing unit 630 may sense/amplify and output data accessed by the fuse array 610. Bits (OUT1 through OUTk) output by the sensing unit 630 may be provided to the register unit 640.

The register unit 640 may receive the bits (OUT1 through OUTk) in the unit of row of the fuse array 610. For example, when any one row of the fuse array 610 is selected, the bits (OUT1 through OUTk) from the fuse AF connected to a word line of the selected row may be provided to the register unit 640 in parallel. The bits (OUT1 through OUTk) stored in the register unit 640 may be output as the operation data MOD for repairing the defective column of the tick.

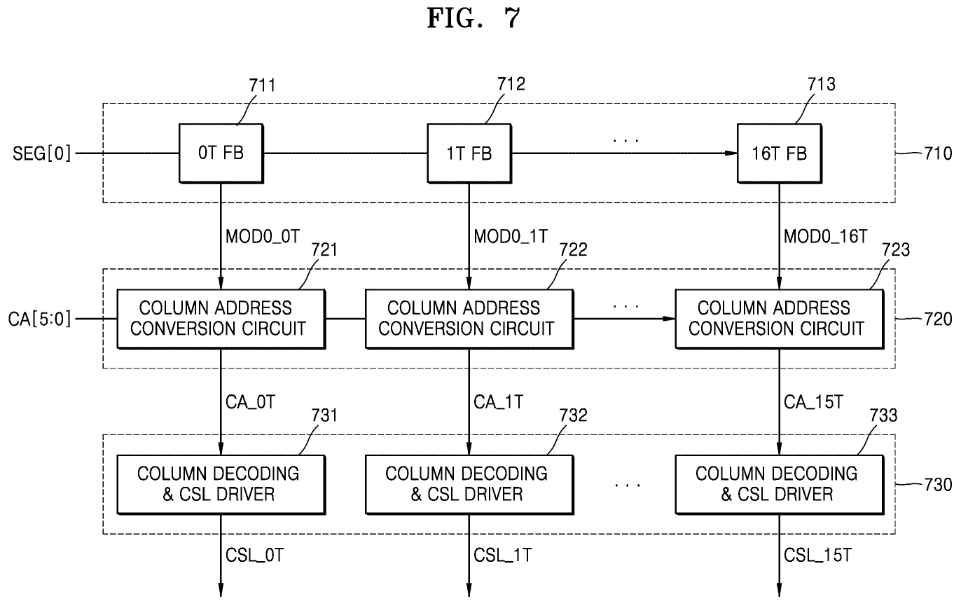

FIG. 7 is a diagram for describing operations of each of a repair address storage circuit 710, a column repair circuit 720, and a column decoder 730, according to some implementations. In FIG. 7, operations of the repair address storage circuit 710, the column repair circuit 720, and the column decoder 730 are described based on the segment SEG[0] in the case where the burst length BL is 16.

Referring to FIG. 7, in some implementations, the column repair circuit 720 may be configured to perform a mathematical operation based on target operation data corresponding to a target segment and the first column address, and may be configured to generate the first remapping column address as a result of the mathematical operation.

Referring to FIG. 7, for example, a column address CA[5:0] to be accessed may be provided to the memory device 100. Although the number of bits of the column address CA[5:0] is shown to be six digits, the disclosure is not limited thereto. When the number of bits of the column address CA[5:0] is 6, the number of columns included in one tick may be 64. The repair address storage circuit 710 may include fuse boxes 0T FB 711, . . . , and 16T FB 713 of 0T tick TICK[0] through 16T tick TICK[15]. The column repair circuit 720 may include column address conversion circuits 721, 722, . . . , 723 respectively corresponding to the 0T tick TICK[0] through 16T tick TICK[15]. The column decoder 730 may include column decoding and column selection line drivers 731, 732, . . . , 733 respectively corresponding to the 0T tick TICK[0] through 16T tick TICK[15].

The fuse boxes 0T FB 711, 1T FB 712, . . . , and 16T FB 713 are the same as described above with reference to FIG. 5. Each of the column address conversion circuits 721, 722, . . . , 723 may output a remapped column address, based on the column address CA[5:0] to be accessed and the operation data MOD for the corresponding segment. Each of the column decoding and column selection line drivers (731, 732, . . . , 733) may output the column selection line signal CSL based on the remapped column address.

Referring to FIG. 7, for example, the fuse box 0T FB 711 of the 0T tick TICK[0] may provide the column repair circuit 720 with the target operation data (for example, target operation data MOD0_0T for the segment SEG[0]) among multiple pieces of operation data MOD set for the 0T tick TICK[0], based on the table pointing signal TPS. The column address conversion circuit 721 of 0T tick TICK[0] may output a remapped column address CA_0T of the 0T tick TICK[0], based on the column address CA[5:0] and the target operation data MOD0_0T. The column decoding and column selection line driver 731 of the 0T tick TICK[0] may output a column selection line signal CSL_0T of 0T tick TICK[0] based on the remapped column address CA_0T. The 1T FB 712 of the 1T tick TICK[1] may provide the column repair circuit 720 with the target operation data (for example, target operation data MOD0_1T for the segment SEG[0]) among the multiple pieces of operation data MOD set for the 1T tick TICK[1], based on the table pointing signal TPS. The column address conversion circuit 722 of the 1T tick TICK[1] may output a remapped column address CA_1T of the 1T tick TICK[1], based on the column address CA[5:0] and the target operation data MOD0_1T, and the column decoding and column selection line driver 732 of the 1T tick TICK[1] may output a column selection line signal CSL_1T of the 1T tick TICK[1] based on the remapped column address CA_1T. Similarly, remapped column addresses (for example, CA_2T through CA_15T) respectively corresponding to 2T tick TICCK[2] through 15T tick TICK[15] may be generated, and column selection line signals (for example, CSL_2T through CSL_15T) based on the remapped column addresses (for example, the CA_2T through CA_15T) may be generated. Furthermore, the 16T FB 713 of the 16T tick TICK[16] may output target operation data MOD0_16T for the segment SEG[0], the column address conversion circuit 723 of the 16T tick TICK[16] may output a remapped column address CA_16T of 16T tick TICK[16] based on the column address CA[5:0] and the target operation data MOD0_16T, and the column decoding and column selection line driver 733 of the 16T tick TICK[16] may output a column selection line signal CSL_16T of 16T tick TICK[16] based on a remapped column address CA_16T.

In some implementations, operation data having a bit value of 0 may be stored in an FB at at least some ticks at which a defective column does not occur. In this case, the remapped column address may be the same as the column address CA[5:0] to be accessed.

In some implementations, the remapped column address may include the same number of bits as the number of bits included in the column address CA[5:0] to be accessed. For example, because the number of bits of the column address CA[5:0] is 6, the number of bits of the remapped column address may also be 6.

In some implementations, the number of bits k of the operation data MOD may be less than or equal to the number of bits of the column address CA[5:0]. For example, when the number of bits of the column address CA[5:0] is 6, k may be an integer equal to or greater than 1 and equal to or less than 6. When k is greater than or equal to 1 and less than or equal to 5, at least one of the bits of the column address CA[5:0] may be bypassed.

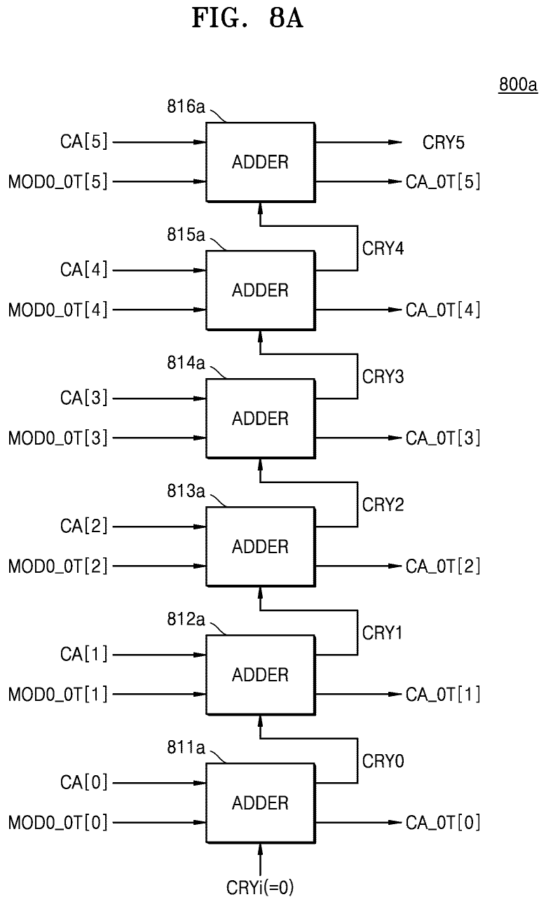

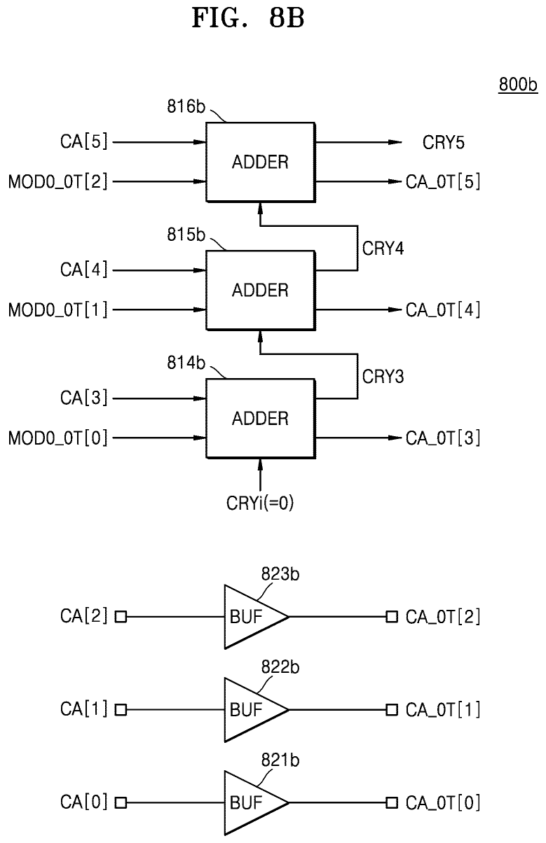

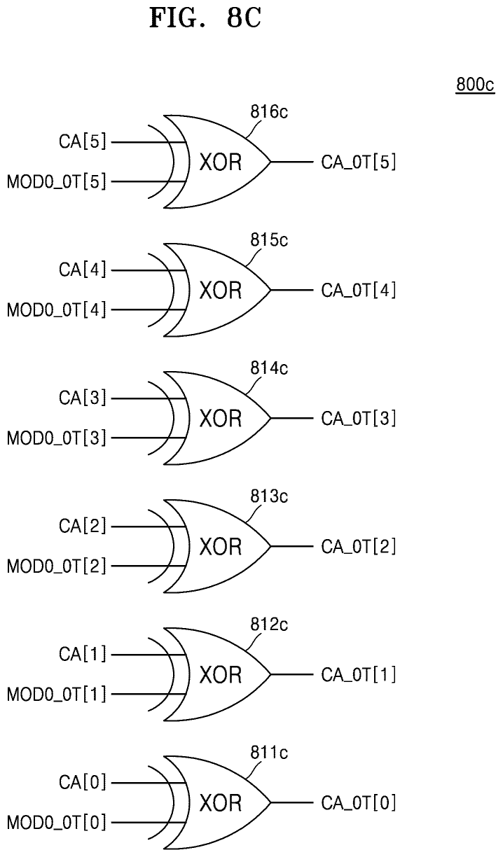

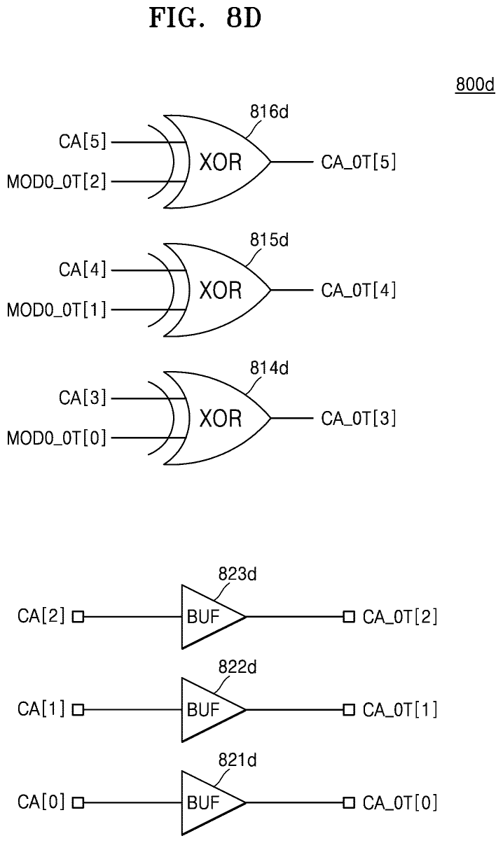

FIGS. 8A, 8B, 8C, and 8D are block diagrams of column address conversion circuits 800a, 800b, 800c, and 800d, according to implementations, respectively. Although FIGS. 8A, 8B, 8C, and 8D illustrate the column address conversion circuit 721 of 0T tick TICK[0], the implementations of FIGS. 8A, 8B, 8C, and 8D of the disclosure may also be applied to the column address conversion circuits 722, . . . , 723 of 1T tick TICK[1] or higher, respectively.

FIGS. 8A and 8B are block diagrams of column address conversion circuits 800a and 800b implemented by at least one adder, respectively.

Referring to FIG. 8A, the column address conversion circuit 800a according to some implementations may include the same number of adders (811a, 812a, 813a, 814a, 815a, and 816a) as the number of bits k of the target operation data MOD0_0T. For example, when k, the number of bits of the target operation data MOD0_0T, is 6 that is equal to the number of bits of the column address CA[5:0], the number of adders included in the column address conversion circuit 800 a may be 6. Each of the six adders (811 a, 812 a, 813 a, 814 a, 815 a, and 816 a) may add a corresponding bit in the column address CA[5:0] and a corresponding bit in the target operation data MOD0_0T of 0T tick TICK[0] for the segment SEG[0].

For example, the adder 811 a may add a first bit CA[0] of the column address CA[5:0] and a first bit MOD0_0T[0] of the target operation data MOD0_0T, and output a first carry CRY0 and a first bit CA_0T[0] of the remapped column address CA_0T. The adder 812a may receive a second bit CA[1] of the column address CA[5:0], a second bit MOD0_0T[1] of the target operation data MOD0_0T, and the first carry CRY0, and by performing an addition operation between the second bits (CA[1] and MOD0_0T[1]) and the first carry CRY0, may output the second carry CRY1 and a second bit CA_0T[1] of the remapped column address CA_0T. Similarly, the remaining adders (813a through 816a) may receive third through sixth bits CA[5:2] of the column address CA[5:0], third through sixth bits MOD0_0T[5:2] of the target operation data MOD0_0T, and second through fifth carries CRY1 through CRY4, respectively, and may output third through sixth carries CRY2 through CRY5 and third through sixth bits CA_0T[5:2] of the remapped column address CA_0T.

In some implementations, the six adders (811a, 812a, 813a, 814a, 815a, and 816a) may be implemented as full adders. In this case, a value of an input carry CRYi input to the adder 811a may be 0.

In some implementations, the adder 811a may be implemented as a half adder, and the five adders (812a, 813a, 814a, 815a, and 816a) may be implemented as full adders. In this case, the input carry CRYi may be omitted.

In the implementation illustrated in FIG. 8A, the number of cases of address remapping between the column addresses and the column selection line signals after the test may be 63 (2 1, where k is 6).

Referring to FIG. 8B, when k, the number of bits of the target operation data MOD0_0T, is 3 that is less than the number of bits of the column address CA[5:0], the column address conversion circuit 800b according to the implementation may include three adders (814b, 815b, and 816b). The three adders (814b, 815b, and 816b) may correspond to the three adders (814a, 815a, and 816a) in FIG. 8A, respectively.

In some implementations, each of the three adders (814b, 815b, and 816b) may be configured to add the upper bit of the column address CA[5:0] and first through third bits MOD0_0T[2:0] of the target operation data MOD0_0T. In this disclosure, an “upper bit” can refer to the most significant bit (MSB) of a digital word, “upper bits” can refer to the most significant bits of the digital word, and N upper bits can refer to the N most significant bits of the digital word. For example, upper bits of the column address CA[5:0] may include fourth through sixth bits CA[5:3]. In this case, the first bit MOD0_0T[0] of the target operation data MOD0_0T may be input to the adder 814b, the second bit MOD0_0T[1] of the target operation data MOD0_0T may be input to the adder 815b, and a third bit MOD0_0T[2] of the target operation data MOD0_0T may be input to the adder 816b.

In some implementations, the three adders (814b, 815b, and 816b) may be implemented as full adders, and a value of an input carry CRYi input to the adder 814b may be 0. In some implementations, the adder 814 b may be implemented as a half adder, and the two adders (815b and 816b) may be implemented as full adders. In this case, the input carry CRYi may be omitted.

In some implementations, each of the three adders (814b, 815b, and 816b) may be configured to add a lower bit of the column address CA[5:0] and the first through third bits MOD0_0T[2:0] of the target operation data MOD0_0T. In this case, the lower bit of the column address CA[5:0] may include first through third bits CA[2:0]. In this disclosure, a “lower bit” can refer to the least significant bit (LSB) of a digital word, “lower bits” can refer to the least significant bits of the digital word, and N lower bits can refer to the N least significant bits of the digital word. In some implementations, each of the three adders (814b, 815b, and 816b) may also be configured to add, at the column address CA[5:0], any three bits of the column address CA[5:0] and the first through third bits MOD0_0T[2:0] of the target operation data MOD0_0T.

In some implementations, bits not input to the adder at the column address CA[5:0], for example, the first through third bits CA[2:0], may be input to the three buffers (821b, 822b, and 823b), and the three buffers (821b, 822b, and 823b) may output the first through third bits CA[2:0] to first through third bits CA_0T[2:0] of the remapped column address CA_0T, respectively. According to the implementations described above, distortion of a signal may be prevented.

In some implementations, three buffers (821b, 822b, and 823b) may be omitted, and the first through third bits CA[2:0] of the column address CA[5:0] may be bypassed via a wire. According to the implementation described above, the size of the column address conversion circuit 800b may be furthermore reduced.

In the implementation illustrated in FIG. 8B, the number of cases of address remapping between the column addresses and the column selection line signals after the test may be 7 (2^{k}-1, where k is 3).

As described above with reference to FIGS. 8A and 8B, the column address remapping may be implemented by performing arithmetic operations (for example, addition) on the values of the target operation data MOD0_0T and the values of the column address CA[5:0].

FIGS. 8C and 8D are block diagrams of column address conversion circuits 800c and 800d implemented by at least one exclusive or (XOR) operator, respectively.

Referring to FIG. 8C, when k, the number of bits of the target operation data MOD0_0T, is 6, that is the same as the number of bits of the column address CA[5:0], the column address conversion circuit 800c may include six XORs (811c, 812c, 813c, 814c, 815c, 816c). Each of the six XORs (811c, 812c, 813c, 814c, 815c, 816c) may perform an XOR operation on bit values of two input signals. Except for the input carry CRYi and first through sixth carries CRY1 through CRY5 in FIG. 8A, bit values input to the six XORs (811c, 812c, 813c, 814c, 815c, 816c) may be the same as described above with reference to FIG. 8A. Because an adder includes one or more XORs and other logical operators, the size of the column address conversion circuit 800c of FIG. 8C may be less than the size of the column address conversion circuit 800a of FIG. 8A. Accordingly, the size of the column address conversion circuit 800c may be reduced.

Referring to FIG. 8D, when k, the number of bits of the target operation data MOD0_0T, is 3 that is less than the number of bits of the column address CA[5:0], the column address conversion circuit 800d may include three XORs (814d, 815d, and 816d). Except for the input carry CRYi and the fourth through sixth carries CRY3 through CRY5 in FIG. 8B, bit values input to the three XORs (814d, 815d, and 816d) may be the same as described above with reference to FIG. 8B. The size of the column address conversion circuit 800d of FIG. 8D may be less than the size of the column address conversion circuit 800c of FIG. 8C.

On the other hand, in some implementations, bits not input to the XOR at the column address CA[5:0], for example, the first through third bits CA[2:0], may be respectively input to the three buffers (821d, 822d, and 823d), and the three buffers (821d, 822d, and 823d) may respectively output the first through third bits CA[2:0] to first to third bits CA_0T[2:0] of the remapped column address CA_0T. According to the implementations described above, distortion of a signal may be prevented.

Alternatively, in some implementations, three buffers (821d, 822d, and 823d) may be omitted, and the first through third bits CA[2:0] of the column address CA[5:0] may also be bypassed via a wire. According to the implementation described above, the size of the column address conversion circuit 800d may be further reduced.

As described above with reference to FIGS. 8C and 8D, the column address remapping may be implemented by performing logical operations (for example, XOR) on the values of the target operation data MOD0_0T and the values of the column address CA[5:0].

Although not illustrated, in some implementations, an exclusive NOR (XNOR) operator may also be applied to the column address conversion circuits 800c and 800d instead of the XOR operator.

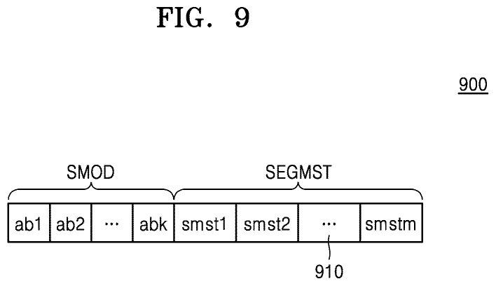

FIG. 9 is a diagram of a fuse box 900 storing shared operation data SMOD according to some implementations. The fuse box 900 corresponding to any one of the plurality of ticks (for example, 0T tick TICK[0]) is illustrated.

Referring to FIGS. 7 and 9, the fuse box 900 may include the shared operation data SMOD and segment master data SEGMST. The shared operation data SMOD may include k bits (ab1, ab2, . . . , abk) as described above with reference to FIG. 5.

The segment master data SEGMST may include data for indicating whether the shared operation data SMOD in FIG. 9 is shared for each segment at one tick (for example, 0T tick TICK[0]). The segment master data SEGMST may include m bits (smst1, smst2, . . . , smstm). Each bit of the segment master data SEGMST may correspond to each segment. For example, the bit smst1 may indicate whether the shared operation data SMOD in FIG. 9 is shared with respect to the first segment SEG[0]. The bit smst2 may indicate whether the shared operation data SMOD in FIG. 9 is shared with respect to the second segment SEG[2]. Similarly, the bit smstm may indicate whether the shared operation data SMOD in FIG. 9 is shared with respect to the mth segment SEG[m-1]. When a bit value of the segment master data SEGMST is ‘1’, the corresponding segment may share the shared operation data SMOD in FIG. 9, and when the bit value of the segment master data SEGMST is ‘0’, the corresponding segment may not share the shared operation data SMOD in FIG. 9. However, the disclosure is not limited thereto, and when the bit value is ‘0’, the corresponding segment may be designed to share the shared operation data SMOD in FIG. 9.

According to descriptions given above, the number of fuses 910 included in one fuse box may be reduced. For example, in FIG. 5, the number of fuses 530 in the fuse box 521 corresponding to the 0T tick TICK[0] may be k*m, whereas the number of fuses 910 in the fuse box 900 may be k+m. Accordingly, the sizes of the repair address storage circuits (131, 500, and 711 through 713) may be reduced.

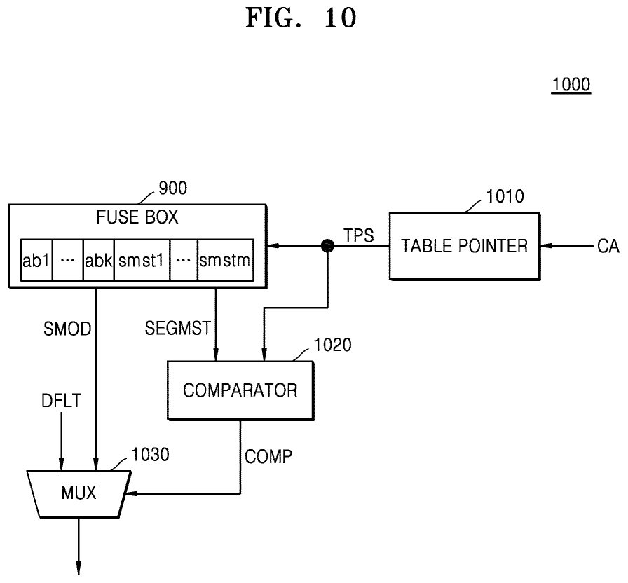

FIG. 10 is a circuit diagram of a repair address storage circuit 1000 including the fuse box 900 in FIG. 9.

Referring to FIG. 10, the repair address storage circuit 1000 may include the fuse box 900, a table pointer 1010, a comparator 1020, and a selector 1030. The fuse box 900 may be the same as described above with reference to FIG. 9. The table pointer 1010 may correspond to the table pointer 510 in FIG. 5. The table pointing signal TPS output by the table pointer 1010 may be provided to the fuse box 900 and the comparator 1020. The fuse box 900 may output the shared operation data SMOD and the segment master data SEGMST based on the table pointing signal TPS. The shared operation data SMOD may be provided to the selector 1030, and the segment master data SEGMST may be provided to the comparator 1020. The comparator 1020 may output a comparison signal COMP based on the segment master data SEGMST and the table pointing signal TPS. The comparator 1020 may compare the segment master data SEGMST to the table pointing signal TPS. When the segment master data SEGMST matches the table pointing signal TPS, the comparison signal COMP may have a first logic level indicating true. When the segment master data SEGMST does not match the table pointing signal TPS, the comparison signal COMP may have a second logic level indicating false. The comparison signal COMP may be input to the selector 1030. The selector 1030 may select the shared operation data SMOD or default data DFLT according to a logic level of the comparison signal COMP. For example, when the logic level of the comparison signal COMP is the first logic level indicating true, the shared operation data SMOD may be selected by the selector 1030. When the logic level of the comparison signal COMP is the second logic level indicating false, the default data DFLT may be selected by the selector 1030. In some implementations, the selector 1030 may be implemented as a multiplexer. The default data DFLT may include, for example, data including at least one ‘0’bit. The default data DFLT output by the selector 1030 may be provided to the column address conversion circuits (800a, 800b, 800c, and 800d) described above with reference to FIGS. 8A, 8B, 8C, and 8D, respectively. In this case, the remapped column address (for example, CA0T[5:0]) may be the same as the column address (for example, CA[5:0]).

Although FIG. 10 illustrates that the repair address storage circuit 1000 includes one fuse box 900, the repair address storage circuit 1000 of FIG. 10 may include not only the fuse box 900 but the fuse boxes for all ticks.

On the other hand, the column repair circuit 720 may be configured to perform a mathematical operation based on the data selected by the selector 1030 and the column address CA. The column repair circuit 720 may be configured to generate the remapping column addresses (for example, CA_0T through CA_15T) as a result of a mathematical operation.

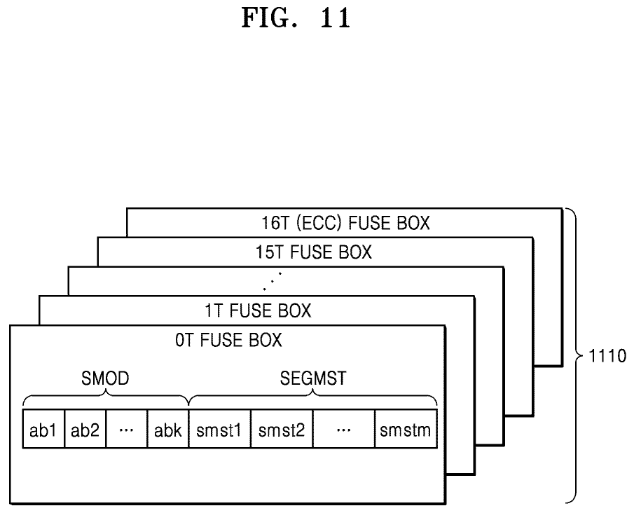

FIG. 11 is an example diagram of fuse boxes 1110 included in the repair address storage circuit 1000 of FIG. 10.

Referring to FIGS. 9, 10, and 11, in some implementations, the repair address storage circuit 1000 may be configured to store at least one piece of shared operation data (for example, one piece of the shared operation data SMOD set for each normal tick), and master data indicating whether the at least one piece of shared operation data is applied to each of the normal ticks or each of the plurality of segments. The master data may include the segment master data SEGMST. In addition, the repair address storage circuit 1000 may be configured to output target shared operation data or the default data DFLT according to the target segment.

Referring to FIG. 11, for example, when the burst length BL is 16, each of the fuse boxes 1110 for the 0T tick TICK[0] through 16T tick TICK[15] may, as described above with reference to FIG. 9, include the shared operation data SMOD and the segment master data SEGMST. Bits (for example, ab1 through abk) of the shared operation data SMOD included in each of the fuse boxes 1110 may be randomly determined for each fuse box.

In some implementations, the number of fuses included in the fuse boxes 1110 may be based on the number of bits of segment master data SEGMST, the number of bits of shared operation data SMOD, and the number of normal ticks. For example, while the number of fuses 530 according to FIG. 5 is k*m*17, the number of fuses included in the fuse boxes 1110 may be 17*(k+m). Accordingly, the sizes of the repair address storage circuits (131, 500, and 711 through 713) may be reduced.

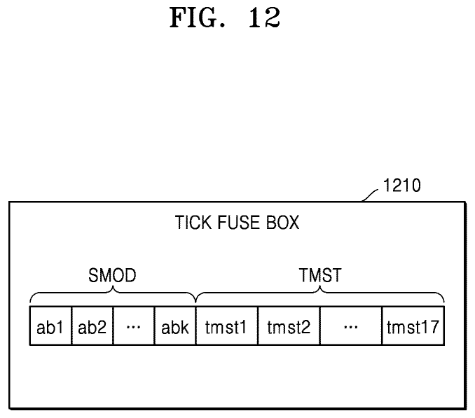

FIG. 12 is a diagram of a fuse box 1210 storing the shared operation data SMOD according to some implementations.

Referring to FIGS. 9, 10, 11, and 12, in some implementations, the repair address storage circuit 1000 may be configured to store the shared operation data SMOD and tick master data TMST indicating whether the shared operation data SMOD is applied to each normal tick. The tick master data TMST may be included in the master data. In addition, the repair address storage circuit 1000 may be configured to output target shared operation data or the default data DFLT according to the target segment.

Referring to FIG. 12, for example, the fuse box 1210 may include the shared operation data SMOD and the tick master data TMST. The tick master data TMST may include data for indicating whether the shared operation data SMOD in FIG. 12 is shared for each tick. For example, when the burst length BL is 16, the tick master data TMST may include 17 bits (tmst1, tmst2, . . . , tmst17). For example, the bit tmst1, the bit tmst2, . . . , and the bit tmstm may indicate whether the shared operation data SMOD in FIG. 12 is shared for 0T tick TICK[0], 1T tick TICK[1], . . . , and 16T tick TICK[16], respectively.

In some implementations, the number of fuses included in one of the fuse box 1210 may be based on the number of bits of the tick master data TMST and the number of bits of the shared operation data SMOD. For example, while the number of fuses included in the fuse boxes 1110 illustrated in FIG. 11 is 17*(k+m), the number of fuses included in the fuse box 1210 may be 17+k. Accordingly, the sizes of the repair address storage circuits (131, 500, and 711 through 713) may be reduced.

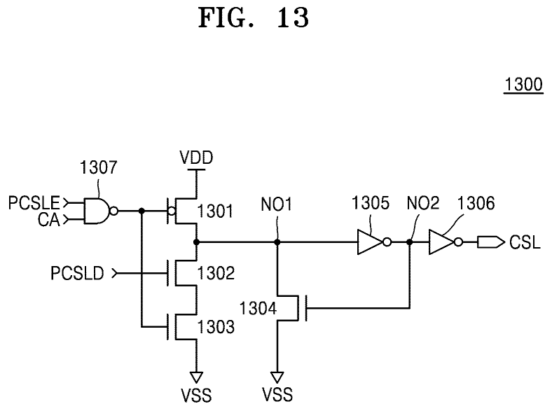

FIG. 13 is a circuit diagram of a column decoding and column selection line driver 1300 according to some implementations.

Referring to FIG. 13, the column decoding and column selection line driver 1300 may include driving transistors (1301, 1302, 1303, 1304), inverters (1305, 1306), and a NAND gate 1307.

The NAND gate 1307 may perform a NAND operation on the column address CA and an active master signal PCSLE. The driving transistor 1301 may include a source connected to a power supply voltage VDD, a gate receiving an output of the NAND gate 1307, and a source connected to a first node NO1. The driving transistor 1302 may include a drain connected to the first node NO1, a gate to which an inactive master signal PCSLD is applied, and a source connected to the driving transistor 1303. The driving transistor 1303 may include a drain connected to the driving transistor 1302, a gate connected to the output of the NAND gate 1307, and a source connected to a ground voltage VSS.

The inverter 1305 may invert a voltage level of the first node NO1 and output the inverted voltage level to a second node NO2, and the inverter 1306 may invert a voltage level of the second node NO2 to output the column selection line signal CSL. The driving transistor 1304 may include a drain connected to the first node NO1, a gate connected to the second node NO2, and a source connected to the ground voltage VSS.

When the column address CA is applied at a high level and the active master signal PCSLE is applied at a high level, the output of the NAND gate 1307 may be at a low level. Accordingly, the driving transistor 1301 may be turned on and the driving transistor 1303 may be turned off. Accordingly, the first node NO1 may be at a high level, the driving transistor 1304 may be turned off, and the inverter 1306 may output the column selection line signal CSL at a high level.

When the active master signal PCSLE at a low level and the inactive master signal PCSLD becomes a high level, the driving transistor 1301 is turned off, and the driving transistors (1302, 1303) may be turned on. Accordingly, the inverter 1306 may output the column selection line signal CSL at a low level. The active master signal PCSLE and the inactive master signal PCSLD may be provided by a pre-decoder provided in the column decoder (for example, 730).

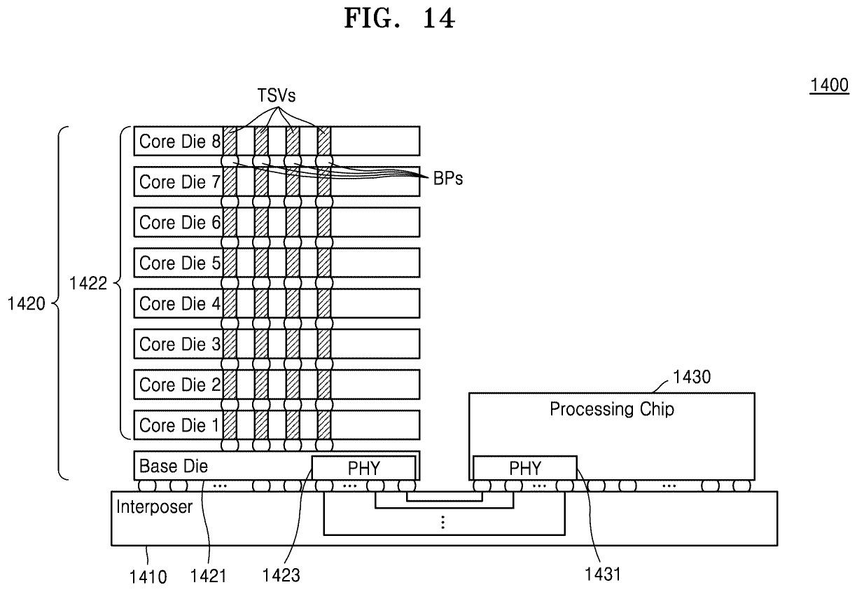

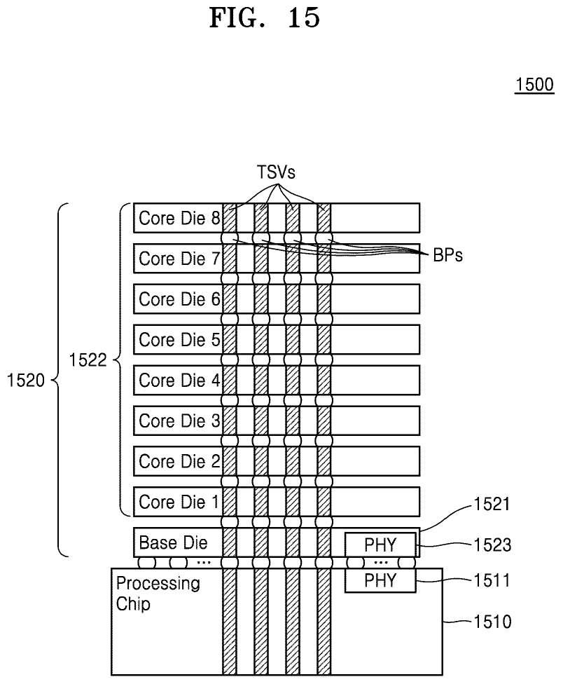

FIGS. 14 and 15 are example diagrams of semiconductor packages 1400 and 1500 including repair circuits of the disclosure, respectively.

Referring to FIG. 14, the semiconductor package 1400 may be implemented as an HBM, and may include an interposer 1410, a memory device 1420, and a processing chip 1430. The memory device 1420 may have a test structure capable of performing a high-speed test by using test equipment in a chip-on wafer state before being packaged. A base die 1421 of the memory device 1420 may be electrically connected to the interposer 1410 via a plurality of micro-bumps BP. A plurality of core dies 1422 of the memory device 1420 may be stacked on the base die 1421, and may include a plurality of micro-bumps BP respectively electrically connected to the plurality of through silicon vias TSV. The processing chip 1430 may include a physical region 1431 electrically connected to a physical region 1423 of the base die 1421 via the interposer 1410. The physical region 1431 may transceive data signals to and from the physical region 1423.

Referring to FIG. 15, the semiconductor package 1500 may include a processing chip 1510 and a memory device 1520 stacked on the processing chip 1510. The memory device 1520 may include a base die 1521 and a plurality of core dies 1522. A physical region 1511 of the processing chip 1510 may be electrically connected to a physical region 1523 of a base die 1221 via the plurality of micro-bumps BP. The plurality of through silicon vias TSV may be formed to penetrate the processing chip 1510.

Each of a plurality of core dies 1422 and a plurality of core dies 1522 may correspond to the memory device 100 in FIG. 1, and the implementations described above with reference to FIGS. 1 through 13 may be applied to each of the plurality of core dies 1422 and each of the plurality of core dies 1522.

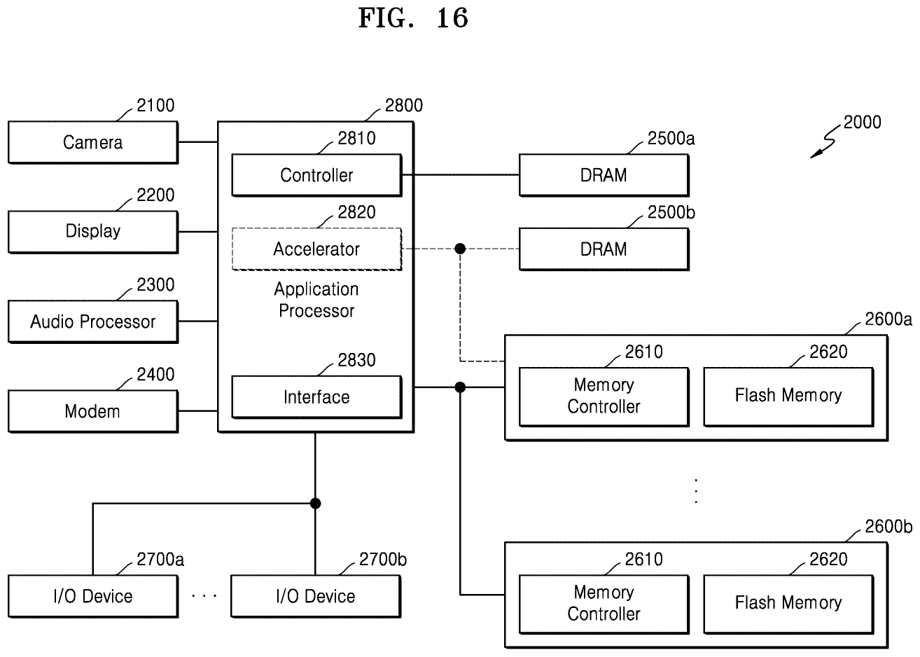

FIG. 16 is a block diagram of a system 2000 including a repair circuit of the disclosure.

Referring to FIG. 16, the system 2000 may be implemented as a mobile device, a server, or a personal computer (PC). An AP 2800 may control the overall operation of each of a camera 2100, a display 2200, an audio processor 2300, a modem 2400, DRAMs (2500a, 2500b), flash memories (2600a, 2600b), and input/output (I/O) devices (2700a, 2700b). The AP 2800 may include an accelerator 2820, which is a dedicated circuit for artificial intelligence (AI) data operations. The AP 2800 may communicate with the DRAM 2500a by using an interface that meets Joint Electron Device Engineering Council (JEDEC) standard standards, such as low power double data rate (LPDDR) LDDR4, LPDDR5, and HBM, and the accelerator chip 2820 may communicate by setting a new DRAM interface protocol to control the DRAM 2500b for accelerators having a higher bandwidth than DRAM 2500a. The accelerator 2820 may perform a training operation and an AI data operation by using the flash memories (2600a, 2600b). The DRAMs (2500a, 2500b) may include the repair circuits described with reference to FIGS. 1 through 13.

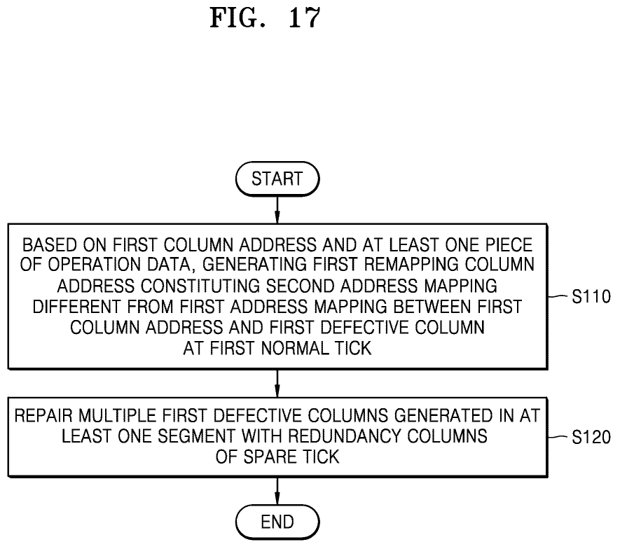

FIG. 17 is a flowchart of a method of operating the memory device 100, according to some implementations.

Referring to FIGS. 1 and 17, in operation S110, the memory device 100 may generate a first remapping column address constituting a second address mapping different from a first address mapping between a first column address and a first defective column at a first normal tick of the memory device 100, based on the first column address input to the memory device 100 and at least one piece of operation data stored in the memory device 100.

In some implementations, operation S110 may include generating a table pointing signal based on the first column address, obtaining target operation data corresponding to a target segment in a first fuse box that stores operation data set for each of a plurality of segments for the first normal tick, and generating the first remapping column address by performing a mathematical operation based on the target operation data and the first column address.

In some implementations, operation S110 may include generating a table pointing signal based on the first column address; obtaining first master data and first shared operation data from at least one fuse box storing shared operation data and master data indicating whether the shared operation data is applied at each normal tick or at each segment, based on a table pointing signal; selecting any one piece of the first shared operation data and default data, based on the first master data and the table pointing signal; and generating the first remapping column address by performing a mathematical operation based on the selected data and the first column address.

In some implementations, operation S110 may include performing a mathematical operation on an upper bit corresponding to the number of bits of at least one piece of operation data among a plurality of bits of the first column address and on the plurality of bits of the at least one piece of operation data, and bypassing remaining bits except for the upper bit among the plurality of bits of the first column address.

In operation S120, the memory device 100 may repair multiple first defective columns generated in at least one segment among the plurality of segments of the memory device 100 with redundancy columns of a spare tick.

In some implementations, a method of operating the memory device 100 may further include generating a second remapping column address constituting a third address mapping different from a second address mapping at a second normal tick, based on the first column address and at least one piece of operation data.

In addition, according to another aspect of the disclosure, there is provided a memory device including a memory cell array including a plurality of rows divided into at least one segment, a plurality of columns divided into normal ticks, and a plurality of redundancy columns of a spare tick, and a repair circuit, based on first column address and pre-stored at least one piece of operation data, configured to generate a remapping column address constituting a one-to-one address mapping different from a first address mapping between the first column address and a defective column for each of the normal ticks, and to repair multiple defective columns generated in the at least one segment with redundancy columns of the spare tick.

In some implementations, the repair circuit may include a plurality of fuse boxes configured to store operation data set at each normal tick and each segment, and a plurality of column address conversion circuits configured to perform a mathematical operation based on target operation data output by each of the plurality of fuse boxes and the first column address, and generate the remapping column address as a result of the mathematical operation.

In some implementations, the number of fuses included in the plurality of fuse boxes may be based on the number of segments, a bit number of one piece of operation data, and the number of normal ticks.

In some implementations, the repair circuit may include a plurality of fuse boxes configured to store shared operation data set at each of the normal ticks and segment master data indicating whether the shared operation data is applied at each of the normal ticks and each segment, and a plurality of column address conversion circuits configured to perform a mathematical operation based on target shared operation data for each of segments to which the shared operation data is applied and the first column address, and generate the remapping column address as a result of the mathematical operation.

In some implementations, the number of fuses included in the plurality of fuse boxes may be based on a bit number of the segment master data, a bit number of the shared operation data, and the number of normal ticks.

In some implementations, the repair circuit may include one of fuse boxes configured to store shared operation data and tick master data indicating whether the shared operation data is applied to each normal tick, and one column address conversion circuit configured to perform a mathematical operation based on target shared operation data for each of normal ticks to which the shared operation data is applied and the first column address, and generate the remapping column address as a result of the mathematical operation.

In some implementations, the number of fuses included in the one fuse box may be based on a bit number of the tick master data and a bit number of the shared operation data.

In some implementations, the repair circuit may include adders having the number corresponding to the bit number of the at least one operation data, the adder is configured to perform an addition operation on bits corresponding to the first column address and bits corresponding to the at least one piece of operation data, and output bits corresponding to the remapping column address.

In some implementations, the repair circuit may include an exclusive logical addition operator having the number corresponding to the bit number of the at least one operation data, and the exclusive logical addition operator is configured to perform an exclusive logical addition operation on bits corresponding to the first column address and bits corresponding to the at least one operation data, and output the bits corresponding to the remapping column address.

In some implementations, the repair circuit, by performing a mathematical operation on upper bits corresponding to the bit number of the at least one piece of operation data among a plurality of bits of the first column address and on the plurality of bits of the at least one piece of operation data, may be configured to generate some bits of remapping column address, and by bypassing remaining bits except for the upper bits among the plurality of bits of the first column address, generate remaining bits of the remapping column address.

It will be clearly understood by the one of ordinary skill in the art that the structure of the disclosure may be variously modified or changed without departing from the scope or the technical idea of the disclosure. When the modifications and changes of the disclosure fall within the scope of the following claims and equivalents, the disclosure is considered to include changes and modifications of the disclosure.

While the implementations have been described herein with reference to specific terms, it should be understood that they have been used only for the purpose of describing the technical idea of the disclosure and not for limiting the scope of the disclosure as defined in the claims. Thus, those with ordinary skill in the art will appreciate that various modifications and equivalent implementations are possible without departing from the scope of the disclosure. Accordingly, the true scope of protection of the disclosure should be determined by the technical idea of the following claims.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory cell array including a plurality of rows divided into a plurality of segments, a plurality of columns divided into a plurality of normal ticks corresponding to a burst data set corresponding to a burst length, and a plurality of redundancy columns of a spare tick; and
a repair circuit configured to, based on a first column address and at least one piece of operation data that is pre-stored:
generate a first remapping column address constituting a second address mapping that is different from a first address mapping that maps between the first column address and a first defective column in a first normal tick, and
based on the first remapping column address, repair multiple first defective columns in at least one segment among the plurality of segments using at least one redundancy column of the plurality of redundancy columns of the spare tick.

2. The memory device of claim 1,
wherein the repair circuit comprises:
a repair address storage circuit configured to store operation data for each normal tick of the plurality of normal ticks and for each segment of the plurality of segments; and
a column repair circuit configured to perform a mathematical operation based on target operation data corresponding to a target segment and the first column address, and to generate the first remapping column address based on the mathematical operation.

3. The memory device of claim 2,
wherein the repair address storage circuit comprises:
a table pointer configured to output a table pointing signal based on the first column address; and
a first fuse box configured to store a plurality of pieces of operation data for the first normal tick, and to provide, to the column repair circuit, the target operation data among the plurality of pieces of operation data based on the table pointing signal.

4. The memory device of claim 1,
wherein the repair circuit comprises:
a repair address storage circuit configured to store at least one piece of shared operation data and master data indicating that the at least one piece of shared operation data is applied to each normal tick of the plurality of normal ticks or to each segment of the plurality of segments, and to output a target shared operation data or default data according to a target segment; and
a column repair circuit configured to perform a mathematical operation based on data output by the repair address storage circuit and the first column address, and to generate the first remapping column address based on the mathematical operation.

5. The memory device of claim 4,
wherein the repair address storage circuit comprises:
a table pointer configured to output a table pointing signal based on the first column address;
a fuse box configured to store the target shared operation data and the master data, and to output the target shared operation data and the master data based on the table pointing signal;
a comparator configured to compare the table pointing signal to the master data, and output a comparison signal; and
a selector configured to provide, to the column repair circuit, data selected according to the comparison signal among the target shared operation data and the default data.

6. The memory device of claim 1,
wherein the repair circuit comprises:
a number of adders corresponding to a bit number of the operation data, and
wherein each adder of the number of adders is configured to perform an addition operation on a corresponding bit in the first column address and a corresponding bit in the operation data, and to output a corresponding bit of the first remapping column address.

7. The memory device of claim 6,
wherein the bit number of the operation data is less than a bit number of the first column address,
wherein each upper bit of a plurality of upper bits corresponding to the bit number of the operation data among a plurality of bits of the first column address is input to a corresponding adder, and
wherein remaining bits except for the plurality of upper bits among the plurality of bits of the first column address are bypassed.

8. The memory device of claim 1,
wherein the repair circuit comprises:
a number of exclusive logical addition operators corresponding to a bit number of the operation data, and
wherein each exclusive logical addition operator of the number of exclusive logical addition operators is configured to perform an exclusive logical addition operation on a corresponding bit in the first column address and a corresponding bit in the operation data, and to output a corresponding bit of the first remapping column address.

9. The memory device of claim 8,
wherein the bit number of the operation data is less than the bit number of the first column address,
wherein plurality of upper bits corresponding to the bit number of the operation data among a plurality of bits of the first column address are respectively input to exclusive logical addition operators, and
wherein remaining bits except for the plurality of upper bits among the plurality of bits of the first column address are bypassed.

10. The memory device of claim 1,
wherein the repair circuit is configured to generate a second remapping column address constituting a third address mapping different from the second address mapping at a second normal tick, based on the first column address and the at least one piece of operation data.

11. A method of operating a memory device comprising:
based on a first column address input to the memory device and at least one piece of operation data stored in the memory device, generating a first remapping column address constituting a second address mapping that is different from a first address mapping that maps between the first column address and a first defective column at a first normal tick of the memory device; and
repairing multiple first defective columns in at least one segment among a plurality of segments of the memory device with at least one redundancy column of a spare tick.

12. The method of claim 11,
wherein generating the first remapping column address comprises:
generating a table pointing signal based on the first column address;
based on the table pointing signal, obtaining target operation data corresponding to a target segment in a first fuse box storing operation data set for each segment of the plurality of segments with respect to the first normal tick; and
performing a mathematical operation based on the target operation data and the first column address, and generating the first remapping column address.

13. The method of claim 11,
wherein generating the first remapping column address comprises:
generating a table pointing signal based on the first column address;
based on the table pointing signal, obtaining first master data and first shared operation data in at least one fuse box storing master data indicating that the first shared operation data is applied at each normal tick or each segment;
based on the first master data and the table pointing signal, selecting a piece of data among the first shared operation data and default data; and
performing a mathematical operation based on selected data and the first column address, and generating the first remapping column address.

14. The method of claim 11,
wherein generating the first remapping column address comprises:
performing a mathematical operation on a plurality of upper bits corresponding to a bit number of the at least one piece of operation data among a plurality of bits of the first column address, and on the plurality of bits of the at least one piece of operation data; and
bypassing remaining bits except for the plurality of upper bits among the plurality of bits of the first column address.

15. The method of claim 11, comprising:
based on the first column address and the at least one piece of operation data, generating a second remapping column address constituting a third address mapping different from the second address mapping at a second normal tick.

16. A memory system comprising: a host configured to generate a command and an address; and
a memory device configured to access a burst data set corresponding to a burst length, based on the command and the address,
wherein the memory device comprises:
a memory cell array including a plurality of rows divided into a plurality of segments, a plurality of columns divided into a plurality of normal ticks corresponding to a burst data set corresponding to a burst length, and a plurality of redundancy columns of a spare tick; and
a repair circuit configured to, based on a first column address and at least one piece of operation data that is pre-stored,
generate a first remapping column address constituting a second address mapping that is different from a first address mapping that maps between the first column address and a first defective column, and
based on the first remapping column address, repair multiple first defective columns in at least one segment among the plurality of segments using at least one redundancy column of the plurality of redundancy columns of the spare tick.

17. The memory system of claim 16,
wherein the repair circuit comprises:
a repair address storage circuit configured to store operation data for each normal tick of the plurality of normal ticks and for each segment of the plurality of segments; and
a column repair circuit configured to perform a mathematical operation based on target operation data corresponding to a target segment and the first column address, and to generate the first remapping column address based on the mathematical operation.

18. The memory system of claim 16,
wherein the repair circuit comprises:
a repair address storage circuit configured to store at least one piece of shared operation data and master data indicating that the at least one piece of shared operation data is applied to each normal tick of the plurality of normal ticks or to each segment of the plurality of segments, and to output a target shared operation data or default data according to a target segment; and
a column repair circuit configured to perform a mathematical operation based on data output by the repair address storage circuit and the first column address, and to generate the first remapping column address based on the mathematical operation.

19. The memory system of claim 16,
wherein the repair circuit comprises:
a number of adders corresponding to a bit number of the operation data, and
wherein each adder of the number of adders is configured to perform an addition operation on a corresponding bit in the first column address and a corresponding bit in the operation data, and to output a corresponding bit of the first remapping column address.

20. The memory system of claim 16,
wherein the repair circuit comprises:
a number of exclusive logical addition operators corresponding to a bit number of the operation data, and
wherein each exclusive logical addition operator of the number of exclusive logical addition operators is configured to perform an exclusive logical addition operation on a corresponding bit in the first column address and a corresponding bit in the operation data, and to output a corresponding bit of the first remapping column address.
